(19) United States
(12) Patent Application Publication
(10) Pub. No.: US 2025/0022505 A1
(43) Pub. Date: Jan. 16, 2025

(54) LOCAL I/O READ CIRCUIT IN MEMORY SYSTEM

(71) Applicant: Micron Technology, Inc., Boise, ID (US)

(72) Inventor: Jiyun Li, Boise, ID (US)

(73) Assignee: Micron Technology, Inc., Boise, ID (US)

(21) Appl. No.: 18/743,561

(22) Filed: Jun. 14, 2024

Related U.S. Application Data
(60) Provisional application No. 63/512,815, filed on Jul. 10, 2023.

(51) Int. Cl. G11C 11/4096; G11C 11/4094; G11C 11/4099

(52) U.S. Cl. CPC G11C 11/4096; G11C 11/4094; G11C 11/4099

(57) ABSTRACT

A semiconductor device includes a column select circuit coupled to a complementary pair of bitlines. The column select circuit includes a pair of p-type transistors each coupled in series with a respective one of the complementary pair of bitlines and configured to provide a voltage on the respective one of the complementary pair of bitlines to a respective one of a complementary pair of local input/output (LIO) lines in response to a column select signal. The semiconductor device further includes a LIO circuit comprising a pair of transistors cross-coupled between the complementary pair of LIO lines. The pair of transistors is configured to transition the complementary pair of LIO lines to complementary values based on values provided on the complementary pair of bitlines.

### CROSS REFERENCE TO RELATED APPLICATION(S)

This application claims the benefit under 35 U.S.C. § 119 of the earlier filing date of U.S. Provisional Application Ser. No. 63/512,815 filed Jul. 10, 2023, the entire contents of which are hereby incorporated by reference in its entirety for any purpose.

### BACKGROUND OF THE INVENTION

High data reliability, high speed of memory access, and reduced chip size are features that are demanded from semiconductor memory. In recent years, there has been an effort to further increase the speed of memory access, while maintain reliability during sense operations. One change has been to pack sense amplifiers into smaller spaces, which may result in narrow spacing between other components. The narrow spacing may lead to performance issues of the sense amplifiers, as the smaller wells may cause certain components of the sense amplifiers to become weaker at sensing data on bitlines coupled to a memory cell array. Difference architectures may be needed to improve sense amplifier performance.

### BRIEF DESCRIPTION OF THE DRAWINGS

FIG. 1 is a schematic block diagram of a semiconductor device 100, in accordance with an embodiment of the present disclosure.

FIG. 2 is a schematic block diagram of a semiconductor device 200, in accordance with an embodiment of the present disclosure.

FIG. 3 is a schematic block diagram of a semiconductor device 300, in accordance with an embodiment of the present disclosure.

FIG. 4 includes an exemplary timing diagram 400 of a read access from a memory cell array, in accordance with embodiments of the disclosure.

### DETAILED DESCRIPTION

This disclosure describes examples of a column select (CS) and local input/output (LIO) and read circuits that is simpler and faster than conventional circuits. The CS/LIO circuits may include a CS circuit having a p-type metal-oxide semiconductor (PMOS) transistors controllable via a column select signal to pass a high signal to the LIO line. The LIO pair may be sensed via a 2n2p architecture (two cross-coupled n-type transistors and two cross-coupled p-type transistors). Because the CS uses the PMOS the column select, the LIO line is capable of being pulled to a full low signal (e.g., as compared with use of n-type metal-oxide semiconductor (NMOS) transistors that is incapable pulling the LIO line to a full low voltage). This allows the read circuit design to be simplified and have a reduced size as compared with a read circuit coupled to a CS/LIO circuit using NMOS CS transistors.

Certain details are set forth below to provide a sufficient understanding of embodiments of the present disclosure. However, it will be clear to one skilled in the art that embodiments of the present disclosure may be practiced without these particular details. Moreover, the particular embodiments of the present disclosure described herein are provided by way of example and should not be used to limit the scope of the disclosure to these particular embodiments. In other instances, well-known circuits, control signals, timing protocols, and software operations have not been shown in detail in order to avoid unnecessarily obscuring the disclosure.

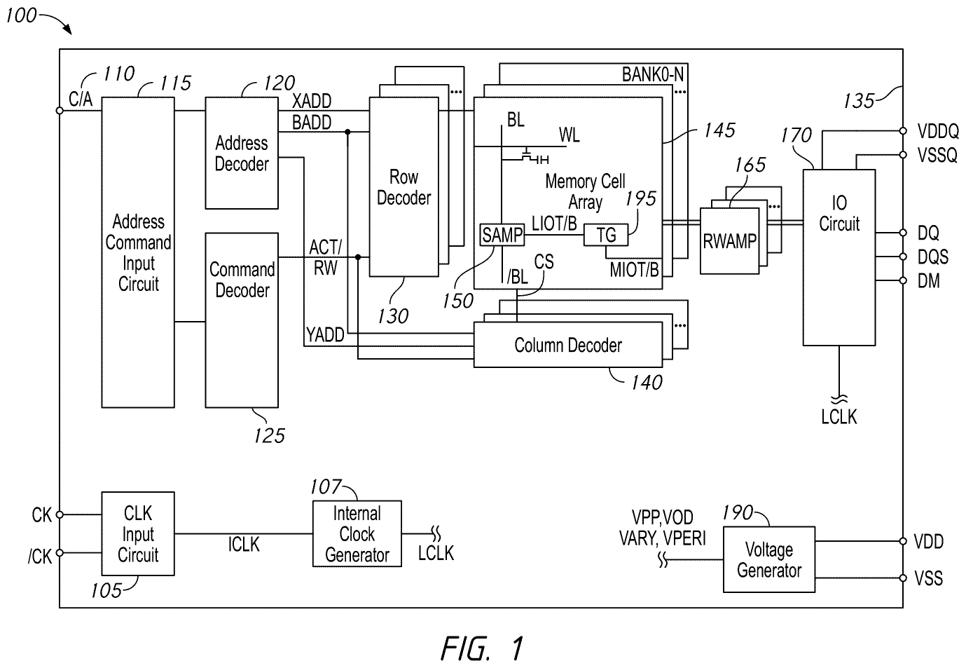

FIG. 1 is a schematic block diagram of a semiconductor device 100, in accordance with an embodiment of the present disclosure. For example, the semiconductor device 100 may include a chip 135. The chip 135 may include a clock input circuit 105, an internal clock generator 107, an address command input circuit 115, an address decoder 120, a command decoder 125, a plurality of row decoders 130, a memory cell array 145 including sense amplifiers 150 and transfer gates 195, a plurality of column decoders 140, a plurality of read/write amplifiers 165, an input/output (I/O) circuit 170, and a voltage generator 190. The semiconductor device 100 may include a plurality of external terminals including address and command terminals coupled to command/address bus 110, clock terminals CK and/CK, data terminals DQ, DQS, and DM, and power supply terminals VDD, VSS, VDDQ, and VSSQ. The chip 135 may be mounted on a substrate, for example, a memory module substrate, a mother board or the like.

The memory cell array 145 includes a plurality of banks BANKO-N, each bank BANKO-N including a plurality of word lines WL, a plurality of bit lines BL, and a plurality of memory cells MC arranged at intersections of the plurality of word lines WL and the plurality of bit lines BL. The number of banks BANKO-N may include 2, 4, 8, 16, or any other number of banks. Each of the banks BANKO-N may divided into two or more memory planes (e.g., column planes), which may be selected by the column select CS signal from the column decoders 140. In some examples, each of the banks BANKO-N may include 2, 4, 8, 16, 32, etc., column planes. The selection of the word line WL for each bank is performed by a corresponding row decoder 130 and the selection of the bit line BL is performed by a corresponding column decoder 140. The plurality of sense amplifiers 150 are located for their corresponding bit lines BL and coupled to at least one respective local I/O line further coupled to a respective one of at least two main I/O line pairs, via transfer gates TG 195, which function as switches.

In some examples, the sense amplifiers 150 may include column select (CS) and local input/output (LIO) circuits and the transfer gates TG 195 may include corresponding read circuits. The CS/LIO circuits may include a CS circuit having a p-type metal-oxide semiconductor (PMOS) transistors controllable via a column select signal to pass a high signal to the LIO line. The LIO pair may be sensed via a 2n2p architecture (two cross-coupled n-type transistors and two cross-coupled p-type transistors). Because the CS uses the PMOS the column select, the LIO line is capable of being pulled to a full low signal (e.g., as compared with use of n-type metal-oxide semiconductor (NMOS) transistors that is incapable pulling the LIO line to a full low voltage). The read circuit may be configured to provide data signals to the MIO line without the use of a cascade circuit. Instead, the MIO line may be coupled to a drain of a single n-type transistor having a gate controlled by the LIO line output from the CS/LIO circuit. This allows the read circuit design to be simplified and have a reduced size as compared with a read circuit coupled to a CS/LIO circuit using NMOS CS transistors.

The address/command input circuit 115 may receive an address signal and a bank address signal from outside at the command/address terminals via the command/address bus 110 and transmit the address signal and the bank address signal to the address decoder 120. The address decoder 120 may decode the address signal received from the address/command input circuit 115 and provide a row address signal XADD to the row decoder 130, and a column address signal YADD to the column decoder 140. The address decoder 120 may also receive the bank address signal and provide the bank address signal BADD to the row decoder 130 and the column decoder 140.

The address/command input circuit 115 may receive a command signal from outside, such as, for example, a memory controller 105 at the command/address terminals via the command/address bus 110 and provide the command signal to the command decoder 125. The command decoder 125 may decode the command signal and provide generate various internal command signals. For example, the internal command signals may include a row command signal to select a word line, a column command signal, such as a read command or a write command, to select a bit line.

When a read command is issued and a row address and a column address are timely supplied with the activation and read commands (ACT/RW), read data is read from a memory cell in the memory cell array 145 designated by the row address and the column address. The read/write amplifiers 165 may receive the read data DQ and provide the read data DQ to the IO circuit 170. The IO circuit 170 may provide the read data DQ to outside via the data terminals DQ, together with a data strobe signal at DQS and/or a data mask signal at DM. Similarly, when the write command is issued and a row address and a column address are timely supplied with the ACT and write commands R/W, and then the input/output circuit 170 may receive write data at the data terminals DQ, together with a data strobe signal at DQS and/or a data mask signal at DM and provide the write data via the read/write amplifiers 165 to the memory cell array 145. Thus, the write data may be written in the memory cell designated by the row address and the column address.

Turning to the explanation of the external terminals included in the semiconductor device 100, the clock terminals CK and/CK may receive an external clock signal and a complementary external clock signal, respectively. The external clock signals (including complementary external clock signal) may be supplied to a clock input circuit 105. The clock input circuit 105 may receive the external clock signals and generate an internal clock signal ICLK. The clock input circuit 105 may provide the internal clock signal ICLK to an internal clock generator 107. The internal clock generator 107 may generate a phase controlled internal clock signal LCLK based on the received internal clock signal ICLK and a clock enable signal CKE from the address/command input circuit 115. Although not limited thereto, a DLL circuit may be used as the internal clock generator 107. The internal clock generator 107 may provide the phase controlled internal clock signal LCLK to the IO circuit 170. The IO circuit 170 may use the phase controller internal clock signal LCLK as a timing signal for determining an output timing of read data.

The power supply terminals may receive power supply voltages VDD and VSS. These power supply voltages VDD and VSS may be supplied to a voltage generator circuit 190. The voltage generator circuit 190 may generate various internal voltages, VPP, VOD, VARY, VPERI, and the like based on the power supply voltages VDD and VSS. The internal voltage VPP is mainly used in the row decoder 130, the internal voltages VOD and VARY are mainly used in the sense amplifiers 150 included in the memory cell array 145, and the internal voltage VPERI is used in many other circuit blocks. The power supply terminals may also receive power supply voltages VDDQ and VSSQ. The IO circuit 170 may receive the power supply voltages VDDQ and VSSQ. For example, the power supply voltages VDDQ and VSSQ may be the same voltages as the power supply voltages VDD and VSS, respectively. However, the dedicated power supply voltages VDDQ and VSSQ may be used for the IO circuit 170.

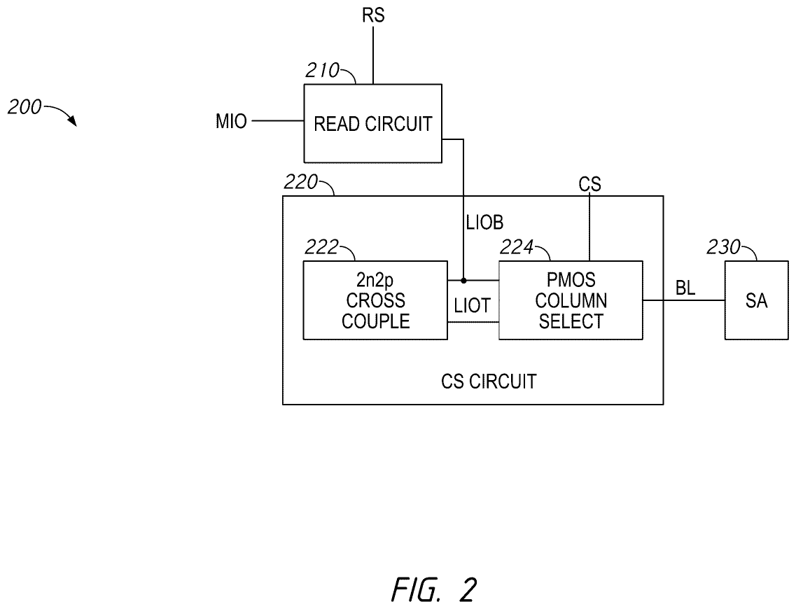

FIG. 2 is a schematic block diagram of a semiconductor device 200, in accordance with an embodiment of the present disclosure. The semiconductor device 200 may include a read circuit 210, a CS/LIO circuits 220, and a sense amplifiers 230. The transfer gates TG 195 of FIG. 1 may implement the semiconductor device 200 of FIG. 2, in some examples.

The sense amplifiers 230 may be coupled to corresponding bit lines to receive data from a memory cell array. During a read operation, the sense amplifiers 230 may sense data read from the memory cell array, and may provide the sensed data to the CS/LIO circuits 220 via a corresponding bitline BL.

The CS/LIO circuits 220 may include LIO circuits 222 and a p-type metal-oxide semiconductor (PMOS) column select circuit 224. The PMOS column select circuit 224 may be coupled to the BL and may be controlled by a column select CS signal. In response to the CS signal being active, the PMOS column select circuit 224 may pass data on the BL to the LIO circuits 222 and to a read circuit 210 via an active high local input/output LIOT line and an active low local input/output LIOB line. The LIO circuits 222 may include a 2n2p architecture that is configured to sense data on the LIOT and LIOTB lines and drive the LIOB line. The read circuit 210 may drive a main input/output MIO line based on the LIOB line.

PMOS column select circuit 224PMOS column select circuit 224PMOS column select circuit 224 In a read operation, a read command along with a read address is received at the semiconductor device 200. Based on the read address, cells of certain rows and/or columns may be activated to read data from a memory cell array. Data from the activated cells may be sensed by the sense amplifiers 230 and driven on the BL. The CS/LIO circuits 220 may be coupled to the BL. The PMOS column select circuit 224 of the CS/LIO circuits 220 may include PMOS transistors controllable via a column select signal to pass a high signal to the LIOB line. The data on the BL line may be sensed via a 2n2p architecture (two cross-coupled n-type transistors and two cross-coupled p-type transistors) of the LIO circuits 222. Because the PMOS column select circuit 224 uses the PMOS the column select, the LIOB line may be capable of being pulled to a full low signal (e.g., as compared with use of n-type metal-oxide semiconductor (NMOS) transistors that is incapable pulling the LIOB line to a full low voltage). In response to the LIOB line and a read select signal, the read circuit 210 may be configured to provide data signals to the MIO line. The read circuit 210 may be capable of driving data on the MIO line using a single n-type transistor having a gate controlled by the LIO line output from the CS/LIO circuit. This allows the read circuit 210 design to be simplified and have a reduced size as compared with a read circuit coupled to a CS/LIO circuit using NMOS CS transistors.

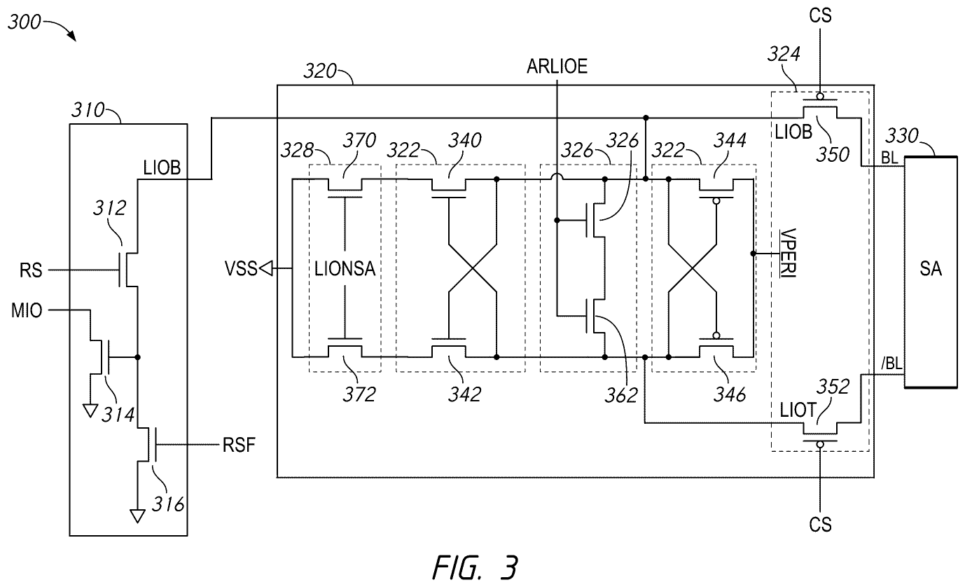

FIG. 3 is a schematic block diagram of a semiconductor device 300, in accordance with an embodiment of the present disclosure. The semiconductor device 300 may include a read circuit 310, a CS/LIO circuits 320, and a sense amplifiers 330. The transfer gates TG 195 of FIG. 1 and/or the semiconductor device 200 of FIG. 2 may implement the semiconductor device 300 of FIG. 3, in some examples.

The sense amplifiers 330 may be coupled a memory cell array to receive data. During a read operation, the sense amplifiers 330 may sense data read from the memory cell array, and may provide the sensed data to the CS/LIO circuits 320 via a complementary pair of corresponding bitlines BL and/BL.

The CS/LIO circuits 320 may include a LIO circuits 322 and a CS circuit 324. The CS circuit 324 may be coupled to the BL and may be controlled by a column select CS signal. The CS circuit 324 may include a first p-type transistor 350 and a second p-type transistor 352 that are each controlled by the CS signal. In response to the CS signal having an active low value, the 350 and the 352 may pass data from the BL and the/BL to the LIOB and LIO lines of the LIO circuits 322, respectively.

The LIO circuits 322 may include a 2n2p architecture (e.g., cross-coupled n-type transistors 340 and 342 (2n) and cross-coupled p-type transistors 344 and 346 (2p)) that is configured to sense data provided through the CS circuit 324 and drive the LIOB line. The LIO circuits 322 may further include an equalization circuit 326 having a pair of n-type transistors 360 and 362 that are configured to equalize the LIOB and LIO lines during an initialization phase of a read operation (e.g., in response to an equalization enable signal ARLIOE). The LIO circuits 322 may further include a control circuit 328 having a pair of n-type transistors 370 and 372 that are configured to control an output to the LIOB line coupled to the read circuit 310.

The read circuit 310 may include a 312 serially coupled with a 316 and controlled by complementary read select RS and active low read select RSF signals, respectively. For example, when the RS signal is active (e.g., and the RSF signal is inactive), the LIOB line may be coupled to the node between the 312 and the 316. When the RS signal is inactive (e.g., and the RSF signal is active), the LIOB line may be decoupled to the node between the 312 and the 316, and the 316 may be set to couple the node between the 312 and the 316 to a reference voltage. The node between the 312 and the 316 may be coupled to a gate of a 314. The 314 may be configured to provide data on a main input/output MIO line based on a value provided at the node between the 312 and the 316.

During a read operation, a read command along with a read address is received at the semiconductor device 300. Based on the read address, cells of certain rows and/or columns may be activated to read data from a memory cell array. Data from the activated cells may be sensed by the sense amplifiers 330 and driven on the BL and/BL. In response to the CS signal having an active low value, the 350 and the 352 of the CS circuit 324 of the CS/LIO circuits 320 may pass data from the BL and the/BL to the LIOB and LIO lines of the LIO circuits 322, respectively.

The cross-coupled n-type transistors 340 and 342 (2n) and the cross-coupled p-type transistors 344 and 346 (2p) of the LIO circuits 322 may be configured to sense data provided through the CS circuit 324 and drive the LIOB line and LIO line.

The LIO circuits 322 may further include the equalization circuit 326 having a pair of n-type transistors 360 and 362 that are configured to equalize the LIOB and LIO lines during an initialization phase of a read operation (e.g., in response to an equalization enable signal ARLIOE). The LIO circuits 322 may further include a control circuit 328 having a pair of n-type transistors 370 and 372 that are configured to control an output to the LIOB line coupled to the read circuit 310. The pair of n-type transistors 370 and 372 of the control circuit 328 may be configured to control an output to the LIOB line coupled to the read circuit 310 during the read operation.

In response to the RS signal being active (e.g., and the RSF signal is inactive), the LIOB line may be coupled to the node between the 312 and the 316, and the 314 may be configured to provide data on the MIO line based on a value of the LIOB line provided at the node between the 312 and the 316.

In between read operations, the RS signal may be set inactive (e.g., and the RSF signal is active), such that the LIOB line may be decoupled to the node between the 312 and the 316, and the 316 may be set to couple the node between the 312 and the 316 to a reference voltage, which may cause the gate of the 314 to be pulled low to deactivate the 314. In addition, the pair of n-type transistors 360 and 362 of the equalization circuit 326 may be are configured to equalize the LIOB and LIO lines during an initialization phase of a read operation (e.g., in response to an equalization enable signal ARLIOE).

The read circuit 310 may be capable of driving data on the MIO line using a single n-type transistor having a gate controlled by the LIOB line output from CS/LIO circuits 320. This allows the read circuit 310 design to be simplified and have a reduced size as compared with a read circuit coupled to a CS/LIO circuit using NMOS CS transistors.

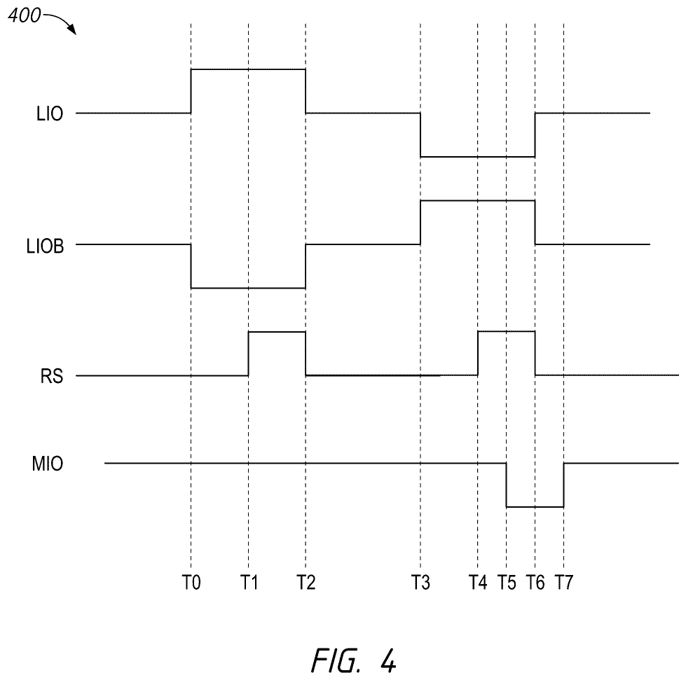

FIG. 4 includes an exemplary timing diagram 400 of a read access from a memory cell array, in accordance with embodiments of the disclosure. The timing diagram 500 may be implemented by the semiconductor device 100 of FIG. 1, the semiconductor device 200 of FIG. 2, and/or the semiconductor device 300 of FIG. 3. Times T0 to T2 represent a read operation having a first data value and times T3 to T7 represent a read operation having a second (complementary) data value.

At time T0, the LIO line may transition to a high logical value and the LIOB line may transition to a low logical value (e.g., in response to CS signals being activated to couple corresponding bitlines BL and/BL to the LIO and LIOB lines). The CS/LIO circuits having a 2n2p architecture (e.g., the CS/LIO circuits 220 of FIG. 2 and/or the CS/LIO circuits 320 of FIG. 3) may drive the LIO and LIOB signal lines based on data received via BL and/BL.

At time T1, the read select RS signal may be set. The RS signal may cause a read circuit (e.g., the read circuit 210 of FIG. 2 and/or the read circuit 310 of FIG. 3) to drive a main input/output MIO line based on a value driven on the LIOB line. Accordingly, at time T2, the MIO line may remain at the high logical value based on the LIOB line having the low logical value.

Between times T2 and T3, the LIO and LIOB lines may equalize (e.g., via the equalization circuit 326 of FIG. 3) and the MIO line may remain low. At time T3, the LIO line may transition to the low logical value and the LIOB line may transition to the high logical value (e.g., in response to CS signals being activated to couple corresponding bitlines BL and/BL to the LIO and LIOB lines). The CS/LIO circuits having a 2n2p architecture may drive the LIO and LIOB signal lines based on data received via BL and/BL.

At time T4, the RS signal may be set. The RS signal may cause the read circuit to drive a main input/output MIO line based on a value driven on the LIOB line. Accordingly, at time T5, the MIO line may transition to the low logical value based on the LIOB line having the high logical value. At time T6, the LIO and LIOB lines may equalize again and the RS signal may transition to the low logical value. Accordingly, at time T7, the MIO line may transition to the high logical value.

As previously noted, the timing diagram 400 is exemplary. The timing relationships are not intended to be to scale, and it is appreciated that other timing relationships may be realized without departing from the scope of the disclosure.

Although the detailed description describes certain preferred embodiments and examples, it will be understood by those skilled in the art that the scope of the disclosure extends beyond the specifically disclosed embodiments to other alternative embodiments and/or uses of the embodiments and obvious modifications and equivalents thereof. In addition, other modifications which are within the scope of the disclosure will be readily apparent to those of skill in the art. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying mode of the disclosed embodiments. Thus, it is intended that the scope of at least some of the present disclosure should not be limited by the particular disclosed embodiments described above.

What is claimed is:

1. An apparatus comprising:
a column select circuit coupled to a complementary pair of bitlines, the column select circuit including a pair of p-type transistors each coupled in series with a respective one of the complementary pair of bitlines and configured to provide a voltage on the respective one of the complementary pair of bitlines to a respective one of a complementary pair of local input/output (LIO) lines in response to a column select signal; and
a LIO circuit comprising a pair of transistors cross-coupled between the complementary pair of LIO lines, wherein the pair of transistors is configured to transition the complementary pair of LIO lines to complementary values based on values provided on the complementary pair of bitlines.

2. The apparatus of claim 1, wherein the pair of transistors of the LIO circuit are each p-type transistors, wherein the LIO circuit further comprises a pair of n-type transistors cross-coupled between the complementary pair of LIO lines, wherein the pair of n-type transistors is configured to transition the complementary pair of LIO lines to the complementary values based on the values provided on the complementary pair of bitlines.

3. The apparatus of claim 1, further comprising a read circuit coupled to one of the complementary pair of LIO lines and configured to, during a read operation, drive a main input/output (MIO) line based on a value provided on the one of the complementary pair of LIO lines.

4. The apparatus of claim 3, wherein the read circuit comprises an n-type transistor having a drain coupled to the MIO line and a gate selectively coupled to the one of the complementary pair of LIO lines based on a read select signal.

5. The apparatus of claim 4, wherein the read circuit further comprises a second n-type transistor configured to couple the gate of the n-type transistor to the one of the complementary pair of LIO lines in response to the read select signal received at a gate of the second n-type transistor being active.

6. The apparatus of claim 5, wherein the read circuit further comprises a third n-type transistor configured to couple the gate of the n-type transistor to a reference voltage in response to the read select signal being inactive.

7. The apparatus of claim 1, wherein the LIO circuit further comprises an equalization circuit configured to couple the complementary pair of LIO lines together during an equalization phase of a read operation.

8. An apparatus comprising:
a column select circuit coupled to a complementary pair of bitlines, the column select circuit including a pair of transistors each coupled in series with a respective one of the complementary pair of bitlines and configured to provide a voltage on the respective one of the complementary pair of bitlines to a respective one of a complementary pair of local input/output (LIO) lines in response to a column select signal; and
a LIO circuit comprising a pair of p-type transistors cross-coupled between the complementary pair of LIO lines and a pair of n-type transistors cross-coupled between the complementary pair of LIO lines, wherein the pair of p-type transistors and the pair of n-type transistors are configured to transition the complementary pair of LIO lines to complementary values based on values provided on the complementary pair of bitlines.

9. The apparatus of claim 8 wherein the pair of transistors of the column select circuit are each p-type transistors.

10. The apparatus of claim 8, further comprising a read circuit coupled to one of the complementary pair of LIO lines and configured to, during a read operation, drive a main input/output (MIO) line based on a value provided on the one of the complementary pair of LIO lines.

11. The apparatus of claim 10, wherein the read circuit comprises:
a first n-type transistor having a drain coupled to the MIO line and a gate selectively coupled to the one of the complementary pair of LIO lines based on a read select signal; and
a second n-type transistor configured to couple the gate of the n-type transistor to the one of the complementary pair of LIO lines in response to the read select signal received at a gate of the second n-type transistor being active.

12. The apparatus of claim 11, wherein the read circuit further comprises a third n-type transistor configured to couple the gate of the n-type transistor to a reference voltage in response to the read select signal being inactive.

13. The apparatus of claim 12, wherein a source of the first n-type transistor of the read circuit is coupled to the reference voltage.

14. The apparatus of claim 8, wherein the LIO circuit further comprises an equalization circuit configured to couple the complementary pair of LIO lines together during an equalization phase of a read operation.

15. An apparatus comprising:
a column select circuit coupled to a complementary pair of bitlines, the column select circuit including a pair of transistors each coupled in series with a respective one of the complementary pair of bitlines and configured to provide a voltage on the respective one of the complementary pair of bitlines to a respective one of a complementary pair of local input/output (LIO) lines in response to a column select signal; and
a LIO circuit comprising a pair of transistors cross-coupled between the complementary pair of LIO lines, wherein the pair of transistors is configured to transition the complementary pair of LIO lines to complementary values based on values provided on the complementary pair of bitlines; and
a read circuit coupled to one of the complementary pair of LIO lines and configured to, during a read operation, drive a main input/output (MIO) line based on a value provided on the one of the complementary pair of LIO lines, wherein the read circuit an n-type transistor having a drain coupled to the MIO line and a gate selectively coupled to the one of the complementary pair of LIO lines based on a read select signal.

16. The apparatus of claim 15, wherein the pair of transistors of the column select circuit are each p-type transistors.

17. The apparatus of claim 15, wherein the pair of transistors of the LIO circuit are each p-type transistors, wherein the LIO circuit further comprises a pair of n-type transistors cross-coupled between the complementary pair of LIO lines, wherein the pair of n-type transistors is configured to transition the complementary pair of LIO lines to the complementary values based on the values provided on the complementary pair of bitlines.

18. The apparatus of claim 15, wherein the read circuit further comprises a second n-type transistor configured to couple the gate of the n-type transistor to the one of the complementary pair of LIO lines in response to the read select signal received at a gate of the second n-type transistor being active.

19. The apparatus of claim 18, wherein the read circuit further comprises a third n-type transistor configured to couple the gate of the n-type transistor to a reference voltage in response to the read select signal being inactive.

20. The apparatus of claim 18, wherein the LIO circuit further comprises an equalization circuit configured to couple the complementary pair of LIO lines together during an equalization phase of a read operation.
